(19) United States
(12) Patent Application Publication
(10) Pub. No.: US 2025/0353757 A1
(43) Pub. Date: Nov. 20, 2025

(54) MATERIAL FOR FILM FORMATION AND METHOD FOR PRODUCING COATING FILM

(71) Applicant: MITSUI MINING & SMELTING CO., LTD., Tokyo (JP)

(72) Inventors: Kento MATSUKURA, Fukuoka (JP); Yuta TANAKA, Fukuoka (JP)

(21) Appl. No.: 18/871,224

(22) PCT Filed: Jul. 19, 2023
(86) PCT No.: PCT/JP2023/026459

§ 371 Date: Dec. 3, 2024

(30) Foreign Application Priority Data
Sep. 9, 2022 (JP) 2022-144166

(51) Int. Cl. C01F 17/259; C01F 17/265; C23C 4/04; C23C 14/06

(52) U.S. Cl. CPC C01F 17/259; C01F 17/265; C23C 4/04; C23C 14/0694; C01P 2002/60; C01P 2002/72; C01P 2004/03; C01P 2004/61; C01P 2004/62; C01P 2006/10

(57) ABSTRACT

A film-forming material is provided in which a rare earth fluoride (REF₃) and a rare earth oxyfluoride (RE-O-F) are observed in X-ray diffraction measurement, and S_{REF3}/S_{RE-O-F} that is a ratio of a crystallite size (S_{REF3}) of REF₃ relative to a crystallite size (S_{RE-O-F}) of RE-O-F is 0.90 or more and 1.35 or less. It is preferable that the crystallite size of each of REF₃ and RE-O-F is 40 nm or more and 100 nm or less. It is also preferable that primary particles observed using a scanning electron microscope (SEM) have an average particle size of 0.1 μm or more and 1.0 μm or less.

### CROSS REFERENCE TO RELATED APPLICATIONS

This application is a 371 U.S. National Phase of International Application No. PCT/JP2023/026459, filed on Jul. 19, 2023, which claims priority to Japanese Patent Application No. 2022-144166, filed Sep. 9, 2022. The entire disclosures of the above applications are incorporated herein by reference.

### BACKGROUND

### Technical Field

The present invention relates to a film-forming material that contains a rare earth fluoride and a rare earth oxyfluoride, and a method for producing a coating film.

### Related Art

Coating films and sintered bodies made of rare earth oxides such as Y₂O₃, rare earth fluorides such as YF₃, and rare earth oxyfluorides such as Y₅O₄F₇ are used as protective materials in the semiconductor manufacturing process as ceramics that have high corrosion resistance.

In particular, it is known that a coating film and a sintered body made of a film-forming material that contains a rare earth oxyfluoride have high chemical plasma corrosion resistance, and can shorten the seasoning time for semiconductor manufacturing equipment.

As a film-forming material that contains a rare earth oxyfluoride and a rare earth fluoride, those disclosed in US 2015/096462 A1, US [0005]

With the film-forming materials disclosed in US 2015/096462 A1, US 2016/326623 A1, and US 2017/114440 A1, there is a relatively large variation in the degree of melting, which may cause an insufficiently melting portion depending on the film-forming condition. Due to this, the resulting coating film may have insufficient corrosion resistance to plasma etching.

Accordingly, it is an object of the present invention to provide a film-forming material that contains a rare earth fluoride and a rare earth oxyfluoride, wherein it is possible to overcome various types of problems encountered with conventional technology as described above.

### SUMMARY

The inventors of the present application conducted in-depth studies on a configuration of a film-forming material that contains a rare earth fluoride and a rare earth oxyfluoride, wherein the corrosion resistance to plasma etching is effectively enhanced. As a result, they found that it is advantageous to adjust the crystallite size of the rare earth fluoride to be the same as or slightly larger than the crystallite size of the rare earth oxyfluoride.

The present invention has been accomplished based on the finding described above, and provides aspects of the present invention according to the following clauses [1] to [11].

[1] A film-forming material in which a rare earth fluoride (REF₃) and a rare earth oxyfluoride (RE-O-F) are observed in X-ray diffraction measurement,
wherein S_{REF3}/S_{RE-O-F} that is a ratio of a crystallite size (S_{REF3}) of REF₃ relative to a crystallite size (S_{RE-O-F}) of RE-O-F is 0.90 or more and 1.35 or less.

[2] The film-forming material as set forth in clause [1],
wherein the crystallite size of each of REF₃ and RE-O-F is 40 nm or more and 100 nm or less.

[3] The film-forming material as set forth in clause [1] or [2],
wherein primary particles observed using a scanning electron microscope (SEM) have an average particle size of 0.1 μm or more and 1.0 μm or less.

[4] The film-forming material as set forth in any one of clauses [1] to [3],
wherein the film-forming material is in a form of granules.

[5] The film-forming material as set forth in clause [4],
wherein a porosity in an internal cross section of the granules observed using an SEM is 10% or more and 35% or less.

[6] The film-forming material as set forth in clause [4] or [5],
wherein the film-forming material in the form of granules has a crushing pressure measured using an SEM indenter of 25 kPa or more and 130 kPa or less.

[7] The film-forming material as set forth in clause [4],
wherein the film-forming material in the form of granules has an average granule particle size of 10 μm or more and 60 μm or less.

[8] The film-forming material as set forth in any one of clauses [1] to [7],
wherein granules have a bulk density of 1.3 g/cm³ or more.

[9] The film-forming material as set forth in any one of clauses [1] to [8],
wherein the film-forming material has an oxygen content of 1 mass % or more and 9 mass % or less.

[10] The film-forming material as set forth in any one of clauses [1] to [9],
wherein the rare earth element (RE) is at least one selected from yttrium (Y), gadolinium (Gd), erbium (Er), and ytterbium (Yb).

[11] A method for producing a coating film including:
forming the film-forming material as set forth in any one of clauses [1] to [10] into the coating film based on a thermal spray method or a PVD method.

### BRIEF DESCRIPTION OF THE DRAWINGS

FIG. 1 is an XRD chart used for crystallite size measurement in Example 1.

FIG. 2 is a scanning electron micrograph used for porosity measurement in Example 1.

FIG. 3 is a scanning electron micrograph before the start of crushing pressure measurement in Example 1.

FIG. 4 is a scanning electron micrograph after the end of the crushing pressure measurement in Example 1.

### DETAILED DESCRIPTION

Hereinafter, the present invention will be described based on a preferred embodiment thereof.

### 1. Film-Forming Material

A film-forming material according to the present invention contains a rare earth element (hereinafter, also referred to as “RE”), and in X-ray diffraction measurement, a rare earth fluoride (hereinafter, also referred to as “REF₃”) and a rare earth oxyfluoride (hereinafter, also referred to as “RE-O-F”) are observed.

As the rare earth element (RE), sixteen rare earth elements including scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) can be used. The film-forming material of the present invention contains at least one of the sixteen rare earth elements. From the viewpoint of even further enhancing the corrosion resistance of a film that is formed based on a method using the film-forming material of the present invention, which will be described later, out of these elements, RE is preferably at least one selected from yttrium (Y), gadolinium (Gd), erbium (Er), and ytterbium (Yb), and more preferably yttrium (Y).

The rare earth oxyfluoride (RE-O-F) is a compound composed of a rare earth element (RE), oxygen (O), and fluorine (F). RE-O-F may be a compound (RE₁O₁F₁) composed of a rare earth element (RE), oxygen (O), and fluorine (F) at a molar ratio of RE:O:F=1:1:1, or any other rare earth oxyfluorides (RE₅O₄F₇, RE₇O₆F₉, RE₄O₃F₆, and the like). From the viewpoint of ease of production of the oxyfluoride and even further enhancing the corrosion resistance of the film that is formed based on the later described method, RE-O-F is preferably represented by REOₓF_{y}, where 0.5≤x≤1 and 1≤y≤2. In particular, from the viewpoint described above, in the above-described formula, x preferably satisfies 0.6≤x≤0.9, and more preferably 0.7≤x≤0.82. Also, y preferably satisfies 1.2≤y≤1.8, and more preferably 1.35≤y≤1.6. Also, in the above-described formula, it is preferable that 2x+y=3 is satisfied.

From the viewpoint described above, the rare earth oxyfluoride is preferably at least one selected from RE₃O₂F₅, RE₄O₃F₆, RE₅O₄F₇, RE₆O₅F₈, and RE₇O₆F₉, and is more preferably RE₅O₄F₇.

In the film-forming material of the present invention, the rare earth element contained in the rare earth oxyfluoride and the rare earth element contained in the rare earth fluoride may be the same or different. However, it is preferable that they are the same. Furthermore, the rare earth oxyfluoride is preferably an oxyfluoride composed of a single rare earth element, and more preferably a single-phase oxyfluoride. As used herein, the term “single phase” refers to a state in which a phase of a single compound of a rare earth oxyfluoride is observed, but a crystal phase of a rare earth oxyfluoride other than that is not observed in XRD analysis.

The film-forming material that contains RE-O-F with a desired composition can be obtained by, for example, in a preferred method for producing a film-forming material, which will be described later, adjusting the amount of hydrofluoric acid added dropwise a first step of the preferred method for producing a film-forming material, or controlling the sintering atmosphere and the sintering temperature as appropriate in a fourth step of the preferred method for producing a film-forming material.

As described above, the film-forming material of the present invention contains REF₃ and RE-O-F. The amount of REF₃ contained in the film-forming material can be controlled by, for example, adjusting the amount of hydrofluoric acid added dropwise in the first step of the preferred method for producing a film-forming material, which will be described later.

It is not easy to accurately measure the amount of fluorine contained in the film-forming material of the present invention. Accordingly, in the present invention, the amount of REF₃ is estimated based on a relative intensity value of the main peak of REF₃ relative to the highest diffraction peak (hereinafter, also referred to as “main peak”) of RE-O-F in a scanning range of 2θ=20° to 60° when the film-forming material is subjected to X-ray diffraction measurement using Cu-Kα rays. Specifically, the ratio (S1/S2) of the intensity (S1) of the main peak of RE-O-F observed in a range of 2θ=20° to 60° and the intensity (S2) of the main peak of REF₃ observed in the same range in X-ray diffraction measurement of particles using Cu-Kα rays is determined. For example, the ratio S1/S2 is preferably 0.05 or more and 35 or less because when the ratio S1/S2 is within this range, a film formed from the film-forming material has excellent corrosion resistance. From this viewpoint, the ratio S1/S2 is more preferably 0.1 or more and 15 or less, even more preferably 0.5 or more and 10 or less, and yet even more preferably 1 or more and 7 or less.

In the XRD analysis in a range of 2θ=20° to 60° using Cu-Kα rays, the main peak of Y₅O₄F₇ is (151) peak, and is usually observed at 2θ=28.11°. Also, the main peak of Y₆O₅F₈ is (161) peak, and is usually observed at 2θ=28.14°. Also, the main peak of Y₇O₆F₉ is (171) peak, and is usually observed at 2θ=28.14°.

The main peak of Gd₄O₃F₆ is (021) peak, and is usually observed at 2θ=27.60°.

The main peak of Er₅O₄F₇ is (151) peak, and is usually observed at 2θ=28.25°.

The main peak of Yb₅O₄F₇ is (151) peak, and is usually observed at 2θ=28.50°.

The main peak of Sm₄O₃F₆ is (111) peak, and is usually observed at 2θ=27.59°.

The main peak of Eu₄O₃F₆ is (111) peak, and is usually observed at 2θ=28.04°.

The main peak of Lu₇O₆F₉ is (171) peak, and is usually observed at 2θ=28.60°.

The main peak of Y₁O₁F₁ is (012) peak, and is usually observed at 2θ=28.74°.

The main peak of Gd₁O₁F₁ is (012) peak, and is usually observed at 2θ=28.20°.

Also, the main peak of YF₃ is (111) peak, and is usually observed at 2θ=27.88°.

The main peak of GdF₃ is (111) peak, and is usually observed at 2θ=27.54°.

The main peak of ErF₃ is (111) peak, and is usually observed at 2θ=27.95°.

The main peak of YbF₃ is (111) peak, and is usually observed at 2θ=27.98°.

The main peak of SmF₃ is (111) peak, and is usually observed at 2θ=27.33°.

The main peak of EuF₃ is (111) peak, and is usually observed at 2θ=27.46°.

The main peak of LuF₃ is (111) peak, and is usually observed at 2θ=27.97°.

However, in the case where, when RE-O-F and REF₃ are observed, their main peaks are detected at close positions (within) 0.4° depending on the combination of compositions such as Y₅O₄F₇ and YF₃, Gd₄O₃F₆ and GdF₃, or Er₅O₄F₇ and ErF₃, the measurement can be performed in the following manner.

Specifically, a numerical value obtained by dividing an intensity (I_{S}) that corresponds to the peak of a predetermined plane, which will be described later, by the relative intensity of a predetermined plane (with the intensity of the main peak being set to 100) (intensity (I_{T}) in PDF cards) may be used as main peak intensity (I_{M}).

$$* {I}_{M} = {I}_{S} / {I}_{T} \times 100$$

The peak in the (010 0) plane of Y₅O₄F₇ is usually observed at 2θ=32.29°, and the relative intensity relative to the main peak is 23.4%.

The peak in the (100) plane of Gd₄O₃F₆ is usually observed at 2θ=31.77°, and the relative intensity relative to the main peak is 14.5%.

The peak in the (171) plane of Er₅O₄F₇ is usually observed at 2θ=32.48°, and the relative intensity relative to the main peak is 14.2%.

The peak in the (002) plane of Sm₄O₃F₆ is usually observed at 2θ=31.91°, and the relative intensity relative to the main peak is 80%.

The peak in the (002) plane of Eu₄O₃F₆ is usually observed at 2θ=32.41°, and the relative intensity relative to the main peak is 80%.

The peak in the (014 0) plane of Lu₇O₆F₉ is usually observed at 2θ=32.87°, and the relative intensity relative to the main peak is 19%.

A predetermined peak of REF₃ can be a peak in the (020) plane.

For example, the peak in the (020) plane of YF₃ is usually observed at 2θ=25.98°, and the relative intensity relative to the main peak is 67.6%.

The peak in the (020) plane of GdF₃ is usually observed at 2θ=25.47°, and the relative intensity relative to the main peak is 60.0%.

The peak in the (020) plane of ErF₃ is usually observed at 2θ=26.03°, and the relative intensity relative to the main peak is 75.0%.

The peak in the (020) plane of SmF₃ is usually observed at 2θ=25.22°, and the relative intensity relative to the main peak is 85%.

The peak in the (020) plane of EuF₃ is usually observed at 2θ=25.37°, and the relative intensity relative to the main peak is 70%.

The peak in the (020) plane of LuF₃ is usually observed at 2θ=26.33°, and the relative intensity relative to the main peak is 90%.

The peak position error is preferably within ±0.05°, more preferably within ±0.03°, even more preferably within ±0.02°, and yet even more preferably within ±0.01°.

In the case where the film-forming material of the present invention contains a combination of Yb₅O₄F₇ and YbF₃, a combination of Y₁O₁F₁ and YF₃, or a combination of Gd₁O₁F₁ and GdF₃, the difference in the main peak position therebetween is 0.52°, 0.86°, and 0.66° at 2θ, respectively, which are greater than 0.4°. For this reason, it is preferable to determine the ratio S1/S2 using the intensity of the main peak.

The main peak ratio between RE-O-F and REF₃ as used in the specification of the present application may be determined based on either one of the following methods: the main peak height ratio is calculated using the peak height (intensity) of a main peak itself; and the main peak height ratio is calculated using a main peak converted height obtained by, as described above, dividing the peak height (intensity) of a peak that is not a main peak by a relative intensity, with the height (intensity) of the main peak described in a PDF card being set to 100. In the case where the main peak ratio can be determined based on the both methods described above, as long as the ratio obtained based on one of the two methods corresponds to a ratio described in the specification of the present application, if the ratio obtained based on the other method does not correspond to the ratio described in the specification of the present application, it is assumed that it corresponds to the ratio described in the specification of the present application.

As can be seen from the fact that the film-forming material of the present invention contains RE-O-F, the film-forming material of the present invention contains oxygen. The amount of oxygen contained in the film-forming material (hereinafter, also referred to as “oxygen content”) is preferably 1 mass % or more and 9 mass %. By adjusting the oxygen content of the film-forming material to 1 mass % or more, for example, as will be described later, in the case where the film-forming material of the present invention is formed into a film based on a thermal spray method, the film-forming material can be supplied in a stable manner during thermal spraying, as a result of which a smooth thermal-sprayed film is likely to be obtained. On the other hand, by adjusting the oxygen content to 9 mass % or less, formation of a rare earth oxide, which will be described later, that is a substance that causes the reduction of the corrosion resistance of the film-forming material, in the film-forming material is effectively prevented, as a result of which it is possible to effectively prevent the reduction of the corrosion resistance of the film formed using the film-forming material. From these viewpoints, the oxygen content of the film-forming material is more preferably 1 mass % or more and 7 mass % or less, and even more preferably 2 mass % or more and 5 mass % or less. In order to adjust the amount of oxygen contained in the film-forming material within the above-described range, for example, in the preferred method for producing a film-forming material, which will be described later, the amount of hydrofluoric acid added dropwise may be adjusted in the first step, or the sintering condition may be adjusted in the fourth step.

The oxygen content of the film-forming material can be measured based on an inert gas melting-infrared absorption method (using a halogen trap).

From the viewpoint of the corrosion resistance of the film and the like, in particular, from the viewpoint of the corrosion resistance to chlorine-based gas, it is preferable that the film-forming material of the present invention does not contain, as much as possible, RE_{Z}O_{W} (hereinafter, also referred to as “rare earth oxide”) that is an oxide composed only of a rare earth element. In order to reduce the amount of RE_{Z}O_{W} contained in the film-forming powder of the present invention as much as possible, for example, in the first step of the preferred method for producing a film-forming material, which will be described later, a rare earth raw material with moderately high reactivity may be used, and the ratio (F/RE) of the number of moles of hydrofluoric acid-derived fluorine atom (F) to the number of moles of rare earth compound-derived rare earth element (RE) may be controlled within a preferred range, which will be described later. Alternatively, in the fourth step of the preferred method for producing a film-forming material, the sintering condition may be adjusted.

It is not easy to quantify the amount of RE_{Z}O_{W} contained in the film-forming powder of the present invention through chemical analysis. Accordingly, in the present invention, the amount of RE_{Z}O_{W} is estimated from the intensity of diffraction peak of the film-forming powder when the film-forming powder is subjected to X-ray diffraction measurement. To be more specific, the film-forming powder of the present invention is subjected to X-ray diffraction measurement using Cu-Kα rays, the ratio (S0/S1) of main peak intensity (S0) of a rare earth oxide observed in a range of 2θ=20° to 60° to main peak intensity (S1) of a rare earth oxyfluoride observed in the same range is determined. In the present invention, the X-ray diffraction measurement is performed based on a powder X-ray diffraction measurement method.

In the present invention, the ratio S0/S1 is preferably 0.1 or less, more preferably 0.05 or less, even more preferably 0.01 or less, and yet even more preferably 0.005 or less. The smaller the ratio S0/S1, the more preferable it is. The ratio S0/S1 is most preferably 0. In the present invention, when the ratio S0/S1 is 0.1 or less, in particular, as small as 0.05 or less, not only high corrosion resistance to fluorine-based plasma, but also high corrosion resistance to chlorine-based plasma can be achieved.

The maximum diffraction peaks of the rare earth oxyfluoride (RE-O-F), the rare earth oxide (RE_{Z}O_{W}), and the rare earth fluoride (REF₃) obtained through powder X-ray diffraction measurement using Cu-Kα rays are usually observed in a range of 2θ=20° to 60°.

For example, the main peak of Y₂O₃ is in the (222) plane, and is usually observed at 2θ=29.14°.

The main peak of Gd₂O₃ is in the (222) plane, and is usually observed at 2θ=28.57°.

The main peak of Er₂O₃ is in the (222) plane, and is usually observed at 2θ=29.21°.

The main peak of Yb₂O₃ is in the (222) plane, and is usually observed at 2θ=29.63°.

The main peak of Sm₂O₃ is in the (222) plane, and is usually observed at 2θ=28.26°.

The main peak of Eu₂O₃ is in the (222) plane, and is usually observed at 2θ=28.42°.

The main peak of Lu₂O₃ is in the (222) plane, and is usually observed at 2θ=29.75°.

The main peak of the rare earth oxide (RE_{Z}O_{W}) is not in close proximity to the peak of the rare earth oxyfluoride (RE-O-F) and the peak of the rare earth fluoride (REF₃), and thus the main peak intensity of RE_{Z}O_{W} can be used when determining the ratio S0/S1.

In the case where the film-forming material of the present invention is produced by sintering an oxalate or a carbonate in the air, the rare earth oxide (RE_{Z}O_{W}) is usually a sesquioxide (RE₂O₃), where z=2 and w=3, except where the rare earth element is cerium (Ce), praseodymium (Pr), or terbium (Tb). Cerium oxide is usually CeO₂, where z=1 and w=2. Praseodymium oxide is usually Pr₆O₁₁, where z=6 and w=11. Terbium oxide is usually Tb₄O₇, where z=4 and w=7. It is possible to produce oxides in other forms such as, for example, Ce₂O₃, Pr₂O₃, PrO₂, and EuO under a special production condition. However, when these oxides are left in the air, they return to their normal forms. Accordingly, the oxides are preferably in the normal forms described above.

In the film-forming material of the present invention, a crystalline phase contained in a compound other than an oxyfluoride of a rare earth element is preferably composed substantially of a fluoride of a rare earth element represented by REF₃ in XRD analysis. As used herein, the expression “a crystalline phase contained in a compound other than an oxyfluoride of a rare earth element is preferably composed substantially of a fluoride of a rare earth element represented by REF₃” means that, in XRD analysis performed using Cu-Kα rays in a scanning range of 2θ=20 to 60°, the peak height of the main peak of a crystalline phase derived from a compound (hereinafter, also referred to as “another component”) other than an oxyfluoride of a rare earth element and a fluoride of a rare earth element represented by REF₃ is preferably 10% or less, more preferably 5% or less, even more preferably 3% or less, and yet even more preferably 1% or less relative to the peak height of the main peak of a RE-O-F-derived crystalline phase.

In the film-forming material of the present invention, the ratio of the crystallite size of REF₃ relative to the crystallite size of RE-O-F satisfies a predetermined relationship. To be more specific, where the crystallite size of RE-O-F determined from a half width of a specific peak of RE-O-F in X-ray diffraction measurement is represented by S_{RE-O-F}, and the crystallite size of REF₃ determined from a half width of a specific peak of REF₃ is represented by S_{REF3}, the ratio (S_{REF3}/S_{RE-O-F}) thereof is 0.90 or more and 1.35 or less. When the ratio S_{REF3}/S_{RE-O-F} is within the above-described range, the coating film formed from the film-forming material has improved corrosion resistance to plasma etching. From this viewpoint, the ratio S_{REF3}/S_{RE-O-F} is preferably 1.00 or more and 1.35 or less, more preferably 1.02 or more and 1.30 or less, and even more preferably 1.04 or more and 1.25 or less. The crystallite size can be determined based on the Scherrer equation, for example, a method described in the Example section, which will be given below. However, a different model may be used as long as the measurement accuracy is the same or higher. The main peak of RE-O-F and the main peak of REF₃ are in close proximity to each other, and thus it is often the case that it is difficult to determine the half width of at least one of RE-O-F and REF₃. For this reason, the crystallite size is calculated by determining a half width of a specific peak that is different from a main peak and is not in close proximity to other peaks.

The angle of a specific peak at 2θ shown below is an angle obtained in XRD analysis performed using Cu-Kα rays in a range of 2θ=20° to 60°.

A specific peak used to determine the crystallite size of RE-O-F will be described.

The specific peak of Y₅O₄F₇ is (0 10 0) peak, and is usually observed at 2θ=32.29°.

The specific peak of Gd₄O₃F₆ is (100) peak, and is usually observed at 2θ=31.77°.

The specific peak of Er₅O₄F₇ is (171) peak, and is usually observed at 2θ=32.48°.

The specific peak of Yb₅O₄F₇ is (171) peak, and is usually observed at 2θ=32.82°.

The specific peak of Sm₄O₃F₆ is (002) peak, and is usually observed at 2θ=31.91°.

The specific peak of Eu₄O₃F₆ is (002) peak, and is usually observed at 2θ=32.41°.

The specific peak of Lu₇O₆F₉ is (0 14 0) peak, and is usually observed at 2θ=32.87°.

The specific peak of Y₁O₁F₁ is (012) peak, and is usually observed at 2θ=28.74°.

The specific peak of Gd₁O₁F₁ is (012) peak, and is usually observed at 2θ=28.20°.

Next, a specific peak used to determine the crystallite size of REF₃ will be described.

In order to determine the crystallite size of REF₃, (020) peak is used.

For example, the specific peak of YF₃ is (020) peak, and is usually observed at 2θ=25.98°.

The specific peak of GdF₃ is (020) peak, and is usually observed at 2θ=25.47°.

The specific peak of ErF₃ is (020) peak, and is usually observed at 2θ=26.03°.

The specific peak of YbF₃ is (020) peak, and is usually observed at 2θ=26.24°.

The specific peak of SmF₃ is (020) peak, and is usually observed at 2θ=25.22°.

The specific peak of EuF₃ is (020) peak, and is usually observed at 2θ=25.37°.

The specific peak of LuF₃ is (020) peak, and is usually observed at 2θ=26.33°.

In the case where the film-forming material of the present invention contains a combination of Yb₅O₄F₇ and YbF₃, a combination of Y₁O₁F₁ and YF₃, or a combination of Gd₁O₁F₁ and GdF₃, it is preferable to use the main peaks thereof to determine the peak intensity ratio therebetween. However, to determine the crystallite sizes thereof, it is preferable that the peaks are more reliably separated from each other. For this reason, the above-described specific peak is used.

The crystallite size can be calculated using the above-described specific peak based on JIS equation (8) specified in JIS K 0131-1996, specifically, 12. Measurement of Crystallite Size and Inhomogeneous Strain in General Rules for X-ray Diffractometric Analysis, or in other words, the so-called Scherrer equation.

At this time, the diffraction data obtained using CuKα rays is separated into diffraction data from Cu-Kα₁ rays and diffraction data from Cu-Kα₂ rays. Then, a diffractogram is created using only Cu-Kα₁ rays, and the half width and the diffraction angle of the specific peak are determined. Also, a standard substance is subjected to measurement, and the half width is corrected.

The crystallite size calculation based on the above-described method can be performed using various types of X-ray diffraction software, for example, PDXL2 available from Rigaku Corporation.

Although the reason that the corrosion resistance to plasma etching is improved when the ratio S_{REF3}/S_{RE-O-F} is within the above-described range is not clearly known, the inventors of the present application consider as follows. Usually, a rare earth oxyfluoride has a melting point higher than that of a rare earth fluoride. When the crystallite size of a rare earth fluoride that has a melting point lower than that of a rare earth oxyfluoride is the same as or slightly larger than the crystallite size of the rare earth oxyfluoride, the particle melting timings of the compositions are about the same. Accordingly, they are uniformly melted, and a smooth coating film is likely to be obtained. Also, the particle energy upon impingement on a substrate is about the same between the rare earth oxyfluoride and the rare earth fluoride, and thus a uniform coating film structure is likely to be obtained. From the reasons described above, the corrosion resistance to plasma etching of the coating film is improved.

The crystallite size S_{REF3} of REF₃ is preferably 40 nm or more and 100 nm or less, more preferably 50 nm or more and 95 nm or less, and even more preferably 60 nm or more and 90 nm or less. When the crystallite size S_{REF3} is 40 nm or more, an advantage of suppressing structural defects of crystal particles to obtain relatively uniform particles with good crystallinity can be obtained. When the crystallite size S_{REF3} is 100 nm or less, an advantage of suppressing excessive grain growth to improve ease of melting of particles can be obtained.

Also, the crystallite size S_{RE-O-F} of RE-O-F is preferably 40 nm or more and 100 nm or less, more preferably 50 nm or more and 95 nm or less, and even more preferably 60 nm or more and 90 nm or less. When the crystallite size S_{RE-O-F} is 40 nm or more and 100 nm or less, the same advantages as those of the crystallite size S_{REF3} can be obtained.

In order to obtain a film-forming material in which S_{REF3} and S_{RE-O-F} satisfy the above-described conditions, for example, in the preferred method for producing a film-forming material of the present invention, which will be described later, an appropriate rare earth compound may be selected in the first step, the crushing condition may be appropriately adjusted in the third step, and the sintering temperature may be appropriately adjusted in the fourth step.

The film-forming material of the present invention has a BET specific surface area of preferably 0.1 m²/g or more and 10 m²/g or less, more preferably 0.5 m²/g or more and 8 m²/g or less, and even more preferably 1 m²/g or more and 6 m²/g or less. When the BET specific surface area is 0.1 m²/g or more, an advantage of appropriately melting the particles during forming the film to obtain a dense coating film can be obtained. Also, when the BET specific surface area is 10 m²/g or less, an advantage of suppressing oxidation of the particles due to thermal effects during forming the film at a high temperature to a certain degree to suppress generation of a rare earth oxide can be obtained. The BET specific surface area is determined based on the BET single-point method.

A film-forming material in which the BET specific surface area is within the above-described range can be obtained by, for example, producing a film-forming material of the present invention using the preferred method for producing a film-forming material of the present invention, which will be described later, and adjusting the type of raw material used in the first step, the crushing condition used in the second step, and the sintering condition used in the fourth step.

The film-forming material of the present invention may be in the form of powders, or may be in the form of granules through granulation. However, the film-forming material of the present invention is preferably in the form of granules from the viewpoint of achieving excellent plasma corrosion resistance of the film of the present invention, and improving the fluidity of the film-forming material to improve ease of supply of the film-forming material during forming the film. Irrespective of the film-forming material of the present invention being in either form, it is preferable that the primary particles of the film-forming material have an average particle size observed using a scanning electron microscope (SEM) of 0.1 μm or more and 1.0 μm or less. When the average particle size of the primary particles is set within the above-described range, an advantage of obtaining the particles with relatively similar kinetic energies to obtain a uniform film quality can be obtained. Also, when the average particle size of the primary particles is set to 1.0 μm or less, the following advantage can be obtained: in the case where the film-forming material of the present invention is in the form of granules, because particles with an appropriate size are present in the granules, granule intensity (the intensity at which the granules can retain their shape against an external force) is increased and ease of supply of the raw material is improved. From these viewpoints, the primary particles of the film-forming material of the present invention have an average particle size of more preferably 0.2 μm or more and 0.9 μm or less, and even more preferably 0.4 μm or more and 0.7 μm or less. In order to adjust the average particle size of the primary particles within this range, for example, in the preferred method for producing a film-forming material, which will be described later, an appropriate rare earth compound may be selected in the first step, the degree of crushing may be adjusted in the second step, or the sintering temperature used in the third step may be adjusted.

The term “average particle size” used herein means an average Feret diameter. The term “Feret diameter” refers to a spacing between two parallel lines tangential to an image of a particle. In the present invention, vertical lines are used as the parallel lines (horizontal Feret diameter).

In the present invention, the film-forming material in the form of granules has an average granule particle size (hereinafter, also referred to as “granule size”) of preferably 10 μm or more and 60 μm or less. When the average granule particle size is set within this range, the fluidity of the film-forming material of the present invention is improved, and a smooth coating film is likely to be obtained. From this viewpoint, the average granule particle size is more preferably 15 μm or more and 55 μm or less, and even more preferably 25 μm or more and 45 μm or less. In order to adjust the average granule particle size within this range, for example, in the preferred method for producing a film-forming material, which will be described later, atomizer's rotation speed in a granulation condition for performing granulation using a spray dryer may be adjusted, or the sintering condition used in the fourth step may be adjusted.

The term “average particle size” used herein refers to a volume cumulative particle size D50 at 50% cumulative volume capacity obtained through measurement using a laser diffraction/scattering particle/granule size distribution measurement device. The method for measuring the particle size D50 will be described in the Example section, which will be given below. The average granule particle size used herein is measured without a sample being subjected to ultrasonication treatment.

In the film-forming material in the form of granules, the granules are composed of primary particles and gaps. The granules have a porosity of preferably 10% or more, the porosity being calculated by observing an internal cross section of the granules using an SEM, and dividing the area of the gaps in the internal cross section by the area of the granules because an advantage of facilitating energy (heat and the like) to be uniformly transmitted to the inside of the granules can be obtained. The porosity is more preferably 15% or more, and even more preferably 20% or more.

Also, the porosity is preferably 35% or less because an advantage of improving the granule intensity to easily obtain a dense coating film can be obtained. The porosity is more preferably 30% or less, and even more preferably 25% or less.

The granules that have a porosity within the above-described range can be obtained by, for example, using the preferred method for producing a film-forming material of the present invention, which will be described later, and adjusting the concentration of a film-forming material precursor slurry used in the third step and the viscosity of the slurry as appropriate. The porosity is measured based on an image in which 30% or more of a cross sectional area of one granule can be observed. Also, as the cross sectional image of the granules, an image in which there are at least 50 or more primary particles in a cross section of one granule is used. A specific method for measuring the porosity will be described in the Example section, which will be given below.

In the present invention, the film-forming material in the form of granules preferably has an appropriate crushing pressure. More specifically, the crushing pressure measured using an SEM indenter is preferably 25 kPa or more from the viewpoint of the granules being unlikely to be broken during transportation. From this viewpoint, the crushing pressure is more preferably 50 kPa or more, and even more preferably 75 kPa or more. The film-forming material in the form of granules preferably has a crushing pressure measured using an SEM indenter of 130 kPa or less from the viewpoint of preventing the granules from being too hard and facilitating improvement of the adhesion to the substrate during forming the film. The crushing pressure is more preferably 115 kPa or less, and even more preferably 100 kPa or less. The crushing pressure measured using an SEM indenter can be measured based on a method described in the Example section, which will be given below, or a different model as long as the model has the same or higher measurement accuracy. The granules that have a crushing pressure within the above-described range can be obtained by, for example, using the preferred method for producing a film-forming material of the present invention, which will be described later, and adjusting the sintering temperature in the fourth step as appropriate.

In the case where the film-forming material of the present invention in the form of granules has a bulk density (also called a “static apparent density”) of preferably 1.3 g/cm³ or more from the viewpoint of increasing the filling rate of the film-forming raw material to a film-forming raw material feeder and improving productivity. From this viewpoint, the bulk density is more preferably 1.4 g/cm³ or more, and even more preferably 2.0 g/cm³ or more.

Also, from the viewpoint of ease of supply and handling of the raw material, the bulk density is preferably 3.0 g/cm³ or less. From this viewpoint, the bulk density is more preferably 2.7 g/cm³ or less, and is even more preferably 2.4 g/cm³ or less.

The bulk density can be measured based on a method described in the Example section, which will be given below. However, a different model may be used as long as the measurement accuracy is the same or higher.

The film-forming material that have a bulk density within the above-described range can be obtained by, for example, producing a film-forming material of the present invention based on the preferred method for producing a film-forming material, which will be given later, and adjusting the crushing condition and the slurry concentration during spraying using a spray dryer.

### 2. Method for Producing Film-Forming Material

Next, a preferred method for producing a film-forming material according to the present invention will be described. In the case where the film-forming material of the present invention is in the form of granules, the film-forming material is produced preferably based on a production method that includes the following first to fourth steps. In the case where the film-forming material in not in the form of granules and in the form of powders, for example, the film-forming material in the form of powders may be subjected directly to the fourth step without performing granulation in the third step.
First step: a step of reacting a rare earth compound and hydrofluoric acid to obtain a film-forming material precursor.
Second step: a step of crushing the film-forming material precursor obtained in the first step to obtain a film-forming material precursor slurry.
Third step: a step of granulating the film-forming material precursor slurry obtained in the second step using a spray dryer to obtain a granulated body.
Fourth step: a step of sintering the granulated body obtained in the third step at a temperature of 300° C. to 900° C. to obtain a film-forming material in the form of granules composed of a rare earth fluoride (REF₃) and a rare earth oxyfluoride (RE-O-F).

Note that the rare earth compound used in the first step includes a rare earth compound poorly soluble or insoluble in water.

Hereinafter, the steps will be described one by one in detail.

### First Step

This step is a step of obtaining a film-forming material precursor.

First, a rare earth compound and pure water is mixed to prepare a solution or a slurry with a predetermined concentration. After that, hydrofluoric acid (an aqueous solution of HF) is added dropwise to the solution or the slurry to perform a fluorination reaction. Next, the slurry that has undergone the fluorination reaction is filtered to obtain a cake. At this time, the filtration is performed preferably using one selected from filtering machines including a vacuum dehydrator, a centrifugal dehydrator, a filter press, and the like from the viewpoint of reducing the number of steps.

In the fluorination reaction, a partial fluorination reaction of the rare earth element proceeds. The fluorination reaction is performed to obtain REF₃ and RE-O-F from the rare earth compound. However, by partially controlling the progress of the fluorination reaction, it is possible to obtain a film-forming material that also contains RE-O-F in addition to REF₃.

With this production method, REF₃ and RE-O-F are simultaneously produced, and it is therefore considered that REF₃ and RE-O-F with a uniform crystallite size are more likely to be obtained as compared with another production method performed by sintering a fluoride to oxidize the fluoride.

From the viewpoint of appropriately controlling the progress of the fluorination reaction, MF/MRE that is a ratio of the number of moles (MF) of hydrofluoric acid-derived fluorine atom (F) relative to the number of moles (MRE) of rare earth compound-derived rare earth element (RE) is preferably more than 1.4 and less than 3.0, more preferably 1.5 or more and 2.8 or less, and even more preferably 1.6 or more and 2.5 or less. The amount of hydrofluoric acid actually used can be adjusted as appropriate within the above-described range according to the intended ratio of REF₃ and RE-O-F in the film-forming material.

As rare earth compound used in the first step, it is preferable to use a rare earth compound poorly soluble or insoluble in water. The rare earth compound poorly soluble or insoluble in water may be at least one or more selected from a rare earth carbonate, a rare earth oxalate, and a rare earth hydroxide. These compounds have moderately high reactivity with hydrofluoric acid. As described above, as a result of the rare earth compound containing at least a rare earth compound that has moderately high reactivity with hydrofluoric acid and is poorly soluble or insoluble in water, the fluorination reaction that takes place when hydrofluoric acid and the rare earth compound are reacted is likely to proceed at an appropriate speed and uniformly.

It is also possible to use a rare earth oxide as the rare earth compound, but the rare earth oxide has a lower reactivity with hydrofluoric acid as compared with the above-described compound, and it takes a long time for the fluorination reaction.

The precursor obtained in the first step may be a component in which a portion of the root of a rare earth compound (for example, carbonate root in the case where the rare earth compound is a rare earth carbonate) is substitute by a fluorine atom.

The reason that, in this production method in which the preferred range of the ratio MF/MRE is more than 1.4 and less than 3.0 as described above, it is preferable to use a rare earth compound poorly soluble or insoluble in water as the rare earth compound will be described below.

If only a water-soluble rare earth compound is used as the rare earth compound, REF₃ is generated by reaction of an aqueous solution of the water-soluble rare earth compound with hydrofluoric acid. Accordingly, unless the ratio MF/MRE_{S} is 3.0 or more, where MRE_{S} indicates the number of moles of the water-soluble and rare earth compound-derived rare earth element (RE_{S}), an unreacted portion of the water-soluble rare earth compound remains. When only a water-soluble rare earth compound is used as the rare earth compound, and the ratio MF/MRE=MF/MRE_{S} is more than 1.4 and less than 3.0, an unreacted portion of the water-soluble rare earth compound remains. Accordingly, only REF₃ can be recovered through solid-liquid separation, and the unreacted portion of the water-soluble rare earth compound cannot be recovered in the form of a solid through the solid-liquid separation. If only full drying is performed without performing solid-liquid separation, it is possible to recover the unreacted portion of the water-soluble rare earth compound in the form of a solid. However, this method not only requires high cost, but also causes the following problem. Because REF₃ and a portion of the rare earth compound that does not contain fluorine are present in a mixed manner, the crystallite size of the component that remains as REF₃ is likely to be much larger than that of RE-O-F generated by reaction of REF₃ and the portion of the rare earth compound that does not contain fluorine during sintering in the fourth step, which will be described later.

Also, if a combination of a water-soluble rare earth compound and a rare earth compound poorly soluble or insoluble in water is used as the rare earth compound, the water-soluble rare earth compound has higher reactivity with hydrofluoric acid, and thus REF₃ is likely to be preferentially generated. When the ratio MF/MRE_{S} is 3 or less, REF₃ is generated. Unless the ratio MF/MRE_{S} is 3, an unreacted portion of the water-soluble compound remains. The rare earth compound poorly soluble or insoluble in water is poorly fluorinated, which results in a mixed state of REF₃ and a fluorine-free portion.

When the ratio MF/MRE_{S} is more than 3, the rare earth compound poorly soluble or insoluble in water is partially fluorinated in a uniform manner. However, there is a difference in fluorine concentration with REF₃ portion, and thus as a whole, fluorination does not proceed uniformly, which may generate REF₃ with a very large crystallite size through sintering in the fourth step, which will be described later. In order to suppress this effect as much as possible, it is preferable to minimize the amount of REF₃ present at the start of sintering in the fourth step, which will be described later. Also, REF₃ generated as a result of fluorination is in the form of very fine particles, and thus from the viewpoint of ease of filtering during filtering in the first step as well, it is preferable to minimize the amount of REF₃ generated as a result of fluorination. Accordingly, MRE_{N}/MRE_{S} that is a ratio of the number of moles (MER_{N}) of the rare earth element (RE_{N}) derived from the rare earth compound poorly soluble or insoluble in water relative to the number of moles (MRE_{S}) of the water-soluble and rare earth compound-derived rare earth element (RE_{S}) is preferably 1 or more, more preferably 2 or more, even more preferably 5 or more, and yet even more preferably 10 or more.

Most preferably, MRE_{S}=0 (MRE_{N}/MRE_{S}=∞), or in other words, to use only the rare earth compound poorly soluble or insoluble in water without using the water-soluble rare earth compound. By using only the rare earth compound poorly soluble or insoluble in water, fluorination proceeds uniformly as a whole. By using only the rare earth compound poorly soluble or insoluble in water, a uniformly fluorinated precursor is obtained, and the precursor decomposes to generate REF₃ and RE-O-F during sintering in the fourth step, which will be described later. Accordingly, the crystallite size of REF₃ will not be too much larger than that of RE-O-F, and REF₃ and RE-O-F with a crystallite size ratio within a desired range are likely to be obtained.

Furthermore, by using only the rare earth compound poorly soluble or insoluble in water, REF₃ in the form of very fine particles is not generated through fluorination, and it is therefore possible to obtain an advantage of allowing filtering to be very easily performed.

Hydrofluoric acid can be added at a rate of, for example, 1 to 50 mol/min, but the present invention is not limited thereto.

### Second Step

In this step, the film-forming material precursor is crushed to obtain a film-forming material precursor slurry. The crushing can be performed using dry crushing and wet crushing. However, it is preferable to use wet crushing from the viewpoint of obtaining a sharp granule size distribution at crushing, and also easily obtaining particles with a uniform particle size. The crushing may be performed in one step, or in two or more steps. From the viewpoint of cost and effort, the crushing is preferably performed in one step. In the case of dry crushing, for example, any type of dry crushing machine can be used such as, for example, a crusher, a jet mill, a ball mill, a hammer mill, and a pin mill. On the other hand, in the case of wet crushing, for example, any type of wet crushing machine can be used such as, for example, a ball mill and a bead mill.

The degree of crushing in the second step is preferably set such that the volume cumulative particle size D50 at 50% cumulative volume capacity obtained through measurement using a laser diffraction/scattering particle/granule size distribution measurement device is 0.1 μm or more and 2.0 μm or less. By crushing the film-forming material precursor to achieve a particle size D50 within the above-described range, uniform granules are easily produced during spraying using a spray dryer in the third step, which will be described later. When the granules are uniform, pores are unlikely to be formed in the resulting film, and thus the corrosion resistance to plasma etching of the film is improved. From this viewpoint, it is more preferable to crush the film-forming material precursor to achieve a particle size D50 of 0.5 μm or more and 1.5 μm or less.

After crushing has been performed in the second step, the concentration of the film-forming material precursor slurry to be subjected to the third step is set to preferably 50 g/L or more and 1500 g/L or less, and more preferably 100 g/L or more and 1000 g/L or less. By setting the slurry concentration within the above-described range, an advantage of easily obtaining a suitable porosity as described above can be obtained. Also, excessive energy consumption in the subsequent steps can be suppressed, and the slurry has an appropriate viscosity, which enables stable spraying in the third step.

### Third Step

In the third step, the slurry obtained in the second step is granulated using a spray dryer to obtain a granulated body of the film-forming material precursor. The rotation speed of an atomizer when operating the spray dryer is preferably set to 5000 min⁻¹ or more and 30000 min⁻¹ or less. By setting the rotation speed to 5000 min⁻¹ or more, a uniform granulated body can be obtained. On the other hand, by setting the rotation speed to 30000 min⁻¹ or less, granules with an intended granule size are likely to be obtained. From these viewpoints, it is more preferable that the rotation speed of the atomizer is 6000 min⁻¹ or more and 25000 min⁻¹ or less.

The inlet temperature when operating the spray dryer is preferably set to 150° C. to 300° C. By setting the inlet temperature to 150° C. or more, the solid component can be sufficiently dried, and thus granules with a low remaining moisture content are likely to be obtained. On the other hand, by setting the inlet temperature to 300° C. or less, wasteful energy consumption can be suppressed.

### Fourth Step

In this step, the granulated body obtained in the fourth step is sintered to obtain a film-forming material in the form of granules that contains a rare earth oxyfluoride including a rare earth fluoride. The degree of sintering serves as a crystallite size controlling factor. To be more specific, the sintering temperature is preferably set to 300° C. to 900° C. By setting the sintering temperature to 300° C. or more, an advantage of removing impurities such as raw material-derived carbon can be obtained. On the other hand, by setting the sintering temperature to 900° C. or less, the following advantages can be obtained: the crystallite size of REF₃ is likely to be a predetermined size or less, the predetermined ratio of the present invention is likely to be obtained, the intended composition is likely to be obtained, and the like. From these viewpoints, the sintering temperature is set to more preferably 400° C. to 800° C., and even more preferably 500° C. to 700° C.

The inventors of the present application consider that, with this production method in which sintering is performed at a relatively low temperature and only once during the process from the reaction between a fluoride and a rare earth compound to the production of a film-forming material, the crystallite size is easily controlled.

The sintering time is preferably 1 hour to 48 hours, and more preferably 3 hours to 24 hours as long as the sintering temperature is within the above-described range. There is no particular limitation on the sintering atmosphere. However, from the viewpoint of cost, the sintering is preferably performed in an oxygen-containing atmosphere such as in the air.

The preferred method for producing a film-forming material described above is superior to a method for producing a film-forming material by mixing previously isolated REF₃ and RE-O-F in that a film-forming material in which REF₃ and RE-O-F are uniformly mixed can be obtained. As a result of REF₃ and RE-O-F being uniformly mixed, a uniform coating film can be obtained, and the coating film has excellent corrosion resistance to plasma etching.

When a film-forming material of the present invention is produced using the preferred method for producing a film-forming material described above, the precursor decomposes during sintering in the fourth step to provide a mixture of REF₃ and RE-O-F. However, it is considered that, in the case where at least RE is Y, Er, or Yb, only RE₅O₄F₇ that has a small oxygen content is likely to be generated as RE-O-F, and RE-O-F that has an oxygen content higher than that of RE₅O₄F₇ such as RE₆O₅F₈, RE₇O₆F₉, and REOF (RE₁O₁F₁) is unlikely to be generated. Also, it is considered that, in the case where RE is at least one selected from Sm, Eu, and Gd, Sm₄O₃F₆, Eu₄O₃F₆, Gd₄O₃F₆, and the like that have a relatively low oxygen content are likely to be generated as RE-O-F.

### 3. Film-Forming Method

Next, a film-forming method that can be used to form a film using the film-forming material of the present invention will be described.

As the film-forming method that can be used in the present invention, mainly, a thermal spray method, a physical vapor deposition method (PVD method), or the like can be used.

### (1) Thermal Spray Method

As the method for thermal spraying the film-forming material of the present invention, flame thermal spraying, high-speed flame thermal spraying, explosion thermal spraying, laser thermal spraying, plasma thermal spraying, laser/plasma composite thermal spraying, or the like can be used.

### (2) Physical Vapor Deposition (PVD) Method

PVD methods can be roughly classified into a sputtering method, a vacuum vapor deposition method, and an ion plating method (see FIG. 4.1.1-3 in Patent Map by Technical Field: Chemical 16 Physical Vapor Deposition published on the Japan Patent Office website, or the like).

The film-forming material of the present invention can be formed into a film using a vacuum vapor deposition method, a sputtering method, or an ion plating method. The vacuum vapor deposition method is a method in which a film is formed by evaporating or sublimating the film-forming material in a vacuum to cause the vapor to reach and deposit on a substrate as the film-forming target. As the vacuum vapor deposition method, it is preferable to use an electron beam method or a laser vapor deposition method because it provides energy sufficiently large to vaporize a powder that contains the rare earth oxyfluoride. The sputtering method is a method in which a film is formed by impinging particles of high energy from a plasma or the like to a material (target) to generate a material component by the impact of the impingement and deposit particles of the generated material component on a substrate. Also, the ion plating method is a film-forming method based on substantially the same principle as the vapor deposition method, except that a film is formed by causing evaporated particles to pass through a plasma atmosphere to positively charge the particles, and applying negative charges to a substrate to attract evaporated particles to deposit on the substrate.

For the film-forming material of the present invention, various types of film-forming methods described above can be suitably used. The resulting films have excellent corrosion resistance to plasma etching. The substrate that serves as the film-forming target may be made of, for example, any type of metal such as aluminum, any type of alloy such as an aluminum alloy, any type of ceramic such as alumina, quartz, or the like.

The film formed from the film-forming material of the present invention has a porosity of preferably 10% or less, and more preferably 5% or less. The lower limit of the porosity is 0%. Also, the film formed from the film-forming material has a surface roughness Ra of preferably 0.01 μm or more and 10 μm or less, and more preferably 0.1 μm or more and 5 μm or less. Also, the film formed from the film-forming material has a surface roughness Rz of preferably 0.1 μm or more and 100 μm or less and more preferably 1 μm or more and 50 μm or less. The porosity, the surface roughness Ra, and the surface roughness Rz can be measured based on a method described in the Example section, which will be given below.

S1′/S2′ that is a ratio of an intensity (S1′) of a main peak of RE-O-F observed in a range of 2θ=20° to 60° in X-ray diffraction measurement of the film using Cu-Kα rays relative to an intensity (S2′) of a main peak of REF₃ observed in the same range is determined. For example, the ratio S1′/S2′ is preferably 0.05 or more and 100 or less from the viewpoint of corrosion resistance. From this viewpoint, the ratio S1′/S2′ is more preferably 0.1 or more and 10 or less, and even more preferably 1 or more and 5 or less.

Also, in the film formed from the film-forming material of the present invention, S0′/S1′ that is a ratio of an intensity (S0′) of a main peak of the rare earth oxide observed in a range of 2θ=20° to 60° in X-ray diffraction measurement using Cu-Kα rays relative to an intensity (S1′) of a main peak of the rare earth oxyfluoride observed in the same range is preferably 0.1 or less, and more preferably 0.01 or less.

The film formed in the present embodiment has excellent plasma corrosion resistance, and thus can be used in applications in semiconductor manufacturing equipment such as a vacuum chamber of an etching apparatus, a sample stage or a chuck in the vacuum chamber, a focus ring, and an etching gas supply inlet, and also as coatings of the constituent members. Also, the film formed in the present embodiment can also be used in applications other than the applications in semiconductor manufacturing equipment and as the constituent members such as various types of plasma processing apparatuses and as constituent members of chemical plants. The film formed in the present embodiment has excellent corrosion resistance to both a fluorine-based plasma and a chlorine-based plasma, as shown in the Example section, which will be given below.

### EXAMPLES

Hereinafter, the present invention will be described in further detail based on examples. However, the scope of the present invention is not limited to the examples given below.

### Example 1

### First Step

20 mol of an yttrium carbonate hydrate (Y₂(CO₃)₃·nH₂O) in terms of yttrium (Y) and pure water were introduced into a synthesis tank and sufficiently stirred and mixed to obtain a slurry containing yttrium at a concentration of 0.5 mol/L. A 50 mass % aqueous solution of HF was added dropwise at a rate of 2.1 mol/min to the obtained slurry in such an amount that F/Y (molar ratio), which is a ratio of fluorine atoms (F) in the aqueous solution of HF added relative to yttrium atoms (Y) in the slurry, was 2.1 to cause a partial fluorination reaction to proceed, and then the slurry that had undergone the fluorination reaction was filtered to obtain a film-forming material precursor cake.

### Second Step

Pure water was added to the film-forming material precursor cake obtained in the first step, and the film-forming material precursor was crushed using a bead mill to achieve a particle size D50 measured using a laser diffraction/scattering particle/granule size distribution measurement device of 0.8 μm. After crushing, pure water was further added to obtain a 500 g/L film-forming material precursor slurry.

The particle size D50 was determined through measurement performed based on the same measurement method as a granule size measurement method, which will be described later, except that, in the granule size measurement method, a sample was added to a chamber of a sample circulator of Microtrac 3300 EXII until the apparatus determined that the concentration reached an appropriate concentration, and then ultrasonic dispersion processing for dispersing the sample was performed at 40 W for 5 minutes using an ultrasonic irradiation device attached to the apparatus before performing measurement.

### Third Step

The film-forming material precursor slurry obtained in the second step was granulated and dried using a spray dryer available from Ohkawara Kakohki Co., Ltd. and a rotating disc as an atomizer to obtain a granulated body. The spray dryer was operated under the following operation condition.
Slurry supply rate: 75 mL/min
Atomizer's rotation speed: 18000 min⁻¹
Inlet temperature: 250° C.

### Fourth Step

The granulated body obtained in the third step was sintered under an air atmosphere in an electric furnace to obtain granulated granules. The sintering temperature was set to 600° C., and the sintering time was set to 5 hours. The granules had a substantially spherical shape. In this way, a film-forming material in the form of granules composed of yttrium fluoride and yttrium oxyfluoride was obtained.

### Example 2

A film-forming material in the form of granules composed of yttrium fluoride and yttrium oxyfluoride was obtained in the same manner as in Example 1, except that the amount of the 50 mass % aqueous solution of HF added dropwise in the first step in Example 1 was changed such that the molar ratio F/Y, which is the ratio of F atoms in the aqueous solution of HF relative to Y atoms in the slurry, was 2.5.

### Example 3

A film-forming material in the form of granules composed of yttrium fluoride and yttrium oxyfluoride was obtained in the same manner as in Example 1, except that the amount of the 50 mass % aqueous solution of HF added dropwise in the first step in Example 1 was changed such that the molar ratio F/Y, which is the ratio of F atoms in the aqueous solution of HF relative to Y atoms in the slurry, was 2.8.

### Example 4

A film-forming material in the form of granules composed of yttrium fluoride and yttrium oxyfluoride was obtained in the same manner as in Example 1, except that the amount of the 50 mass % aqueous solution of HF added dropwise in the first step in Example 1 was changed such that the molar ratio F/Y, which is the ratio of F atoms in the aqueous solution of HF relative to Y atoms in the slurry, was 1.6.

### Example 5

A film-forming material in the form of granules composed of yttrium fluoride and yttrium oxyfluoride was obtained in the same manner as in Example 2, except that the atomizer's rotation speed in the third step in Example 2 was changed to 12000 min⁻¹.

### Example 6

A film-forming material in the form of granules composed of yttrium fluoride and yttrium oxyfluoride was obtained in the same manner as in Example 2, except that, in the second step in Example 2, the film-forming material precursor was crushed to achieve a particle size D50 of 0.3 μm, after crushing, pure water was further added to obtain a 350 g/L slurry, and, in the third step, the mixed slurry was sprayed using a two-fluid nozzle instead of the rotating disc.

### Example 7

A film-forming material in the form of granules composed of gadolinium fluoride and gadolinium oxyfluoride was obtained in the same manner as in Example 1, except for the following changes. In the first step in Example 1, instead of yttrium carbonate hydrate, 10 mol of a gadolinium carbonate hydrate (Gd₂(CO₃)₃·nH₂O) in terms of gadolinium (Gd) and pure water were introduced into a synthesis tank and sufficiently stirred and mixed to obtain a slurry containing gadolinium at a concentration of 0.2 mol/L. A 50 mass % aqueous solution of HF was added dropwise to the obtained slurry in such an amount that F/Gd (molar ratio), which is a ratio of fluorine atoms (F) in the aqueous solution of HF added relative to gadolinium atoms (Gd) in the slurry, was 2.8.

### Example 8

A film-forming material in the form of granules composed of gadolinium fluoride and gadolinium oxyfluoride was obtained in the same manner as in Example 7, except that, in the first step in Example 7, the amount of the 50 mass % aqueous solution of HF added dropwise was changed such that the molar ratio F/Gd, which is the ratio of F atoms in the aqueous solution of HF relative to Gd atoms in the slurry, was 2.5.

### Example 9

A film-forming material in the form of granules composed of gadolinium fluoride and gadolinium oxyfluoride was obtained in the same manner as in Example 7, except that, in the first step in Example 7, the amount of the 50 mass % aqueous solution of HF added dropwise changed such that the molar ratio F/Gd, which is the ratio of F atoms in the aqueous solution of HF relative to Gd atoms in the slurry, was 2.0.

### Example 10

A film-forming material in the form of granules composed of gadolinium fluoride and gadolinium oxyfluoride was obtained in the same manner as in Example 7, except that, in the first step in Example 7, the amount of the 50 mass % aqueous solution of HF added dropwise was changed such that the molar ratio F/Gd, which is the ratio of F atoms in the aqueous solution of HF relative to Gd atoms in the slurry, was 1.8.

### Example 11

A film-forming material in the form of granules composed of erbium fluoride and erbium oxyfluoride was obtained in the same manner as in Example 1, except for the following changes. In the first step in Example 1, instead of yttrium carbonate hydrate, 10 mol of an erbium carbonate hydrate (Er₂(CO₃)₃·nH₂O) in terms of erbium (Er) and pure water were introduced into a synthesis tank and sufficiently stirred and mixed to obtain a slurry containing erbium at a concentration of 0.2 mol/L. A 50 mass % aqueous solution of HF was added dropwise to the obtained slurry in such an amount that F/Er (molar ratio), which is a ratio of fluorine atoms (F) relative to erbium atoms (Er), was 2.7.

### Example 12

A film-forming material in the form of granules composed of erbium fluoride and erbium oxyfluoride was obtained in the same manner as in Example 11, except that, in the first step in Example 11, the amount of the 50 mass % aqueous solution of HF added dropwise was changed such that the molar ratio F/Er, which is the ratio of F atoms in the aqueous solution of HF relative to Er atoms in the slurry was 2.5.

### Example 13

A film-forming material in the form of granules composed of erbium fluoride and erbium oxyfluoride was obtained in the same manner as in Example 11, except that, in the first step in Example 11, the amount of the 50 mass % aqueous solution of HF added dropwise was changed such that the molar ratio F/Er, which is the ratio of F atoms in the aqueous solution of HF relative to Er atoms in the slurry was 2.0.

### Example 14

A film-forming material in the form of granules composed of ytterbium fluoride and ytterbium oxyfluoride was obtained in the same manner as in Example 1, except for the following changes. In the first step in Example 1, instead of yttrium carbonate hydrate, 10 mol of a ytterbium carbonate hydrate (Yb₂(CO₃)₃·nH₂O) in terms of ytterbium (Yb) and pure water were introduced into a synthesis tank and sufficiently stirred and mixed to obtain a slurry containing ytterbium at a concentration of 0.2 mol/L. A 50 mass % aqueous solution of HF was added dropwise to the obtained slurry in such an amount that F/Yb (molar ratio), which is a ratio of fluorine atoms (F) relative to ytterbium atoms (Yb), was 2.7.

### Example 15

A film-forming material in the form of granules composed of ytterbium fluoride and ytterbium oxyfluoride was obtained in the same manner as in Example 14, except that in the first step in Example 14, the amount of the 50 mass % aqueous solution of HF added dropwise was changed such that the molar ratio F/Yb was 2.5 times.

### Example 16

A film-forming material in the form of granules composed of ytterbium fluoride and ytterbium oxyfluoride was obtained in the same manner as in Example 14, except that, in the first step in Example 14, the amount of the 50 mass % aqueous solution of HF added dropwise was changed such that the molar ratio F/Yb was 2.0 times.

### Comparative Example 1

A film-forming material in the form of granules composed of yttrium oxyfluoride was obtained in the same manner as in Example 5, except that, in the first step in Example 5, a 50 mass % aqueous solution of HF was added dropwise such that the molar ratio F/Y was 1.4.

### Comparative Example 2

A film-forming material in the form of granules composed of yttrium oxyfluoride was obtained in the same manner as in Example 5, except that, in the first step in Example 5, a 50 mass % aqueous solution of HF was added dropwise such that the molar ratio F/Y was 1.0.

### Comparative Example 3

Yttrium fluoride (YF₃) was sintered under an air atmosphere in an electric furnace at a sintering temperature of 1050° C. for a sintering time of 12 hours. The obtained sintered article was crushed by means of wet crushing to achieve a particle size D50 of 1 to 2 μm. After that, pure water was added to obtain a 500 g/L slurry, and the obtained slurry was granulated using a spray dryer (atomizer: a rotating disc). The spray dryer was operated under the following operation condition.
Slurry supply rate: 300 mL/min
Atomizer's rotation speed: 12000 min⁻¹
Inlet temperature: 200° C.

The obtained granulated powder was sintered under an air atmosphere in an electric furnace at a sintering temperature 600° C. for a sintering time of 12 hours. In this way, a film-forming material in the form of granules composed of yttrium fluoride and yttrium oxyfluoride was obtained.

### Comparative Example 4

30 wt % of yttrium oxide (Y₂O₃) and 70 wt % of ammonium fluoride double salt ((YF₃)₃NH₄F·H₂O) were mixed. After that, pure water was added to obtain a 500 g/L slurry, and the obtained slurry was granulated using a spray dryer (atomizer: a rotating disc). The spray dryer was operated under the following operation condition.
Slurry supply rate: 300 mL/min
Atomizer's rotation speed: 12000 min⁻¹
Inlet temperature: 200° C.

The obtained granulated powder was sintered under a vacuum atmosphere in an electric furnace at a sintering temperature of 900° C. for a sintering time of 12 hours. In this way, a film-forming material in the form of granules composed of yttrium fluoride and yttrium oxyfluoride was obtained.

### Comparative Example 5

Yttrium fluoride (YF₃ with a particle size D50 of 0.6 μm) and Y₅O₄F₇ (with a particle size D50 of 1 μm) were mixed and formed into a slurry. The slurry was granulated using a spray dryer (atomizer: a rotating disc) to obtain a film-forming material in the form of granules composed of yttrium fluoride and yttrium oxyfluoride. The spray dryer was operated under the following operation condition.
Slurry supply rate: 300 mL/min
Atomizer's rotation speed: 9000 min⁻¹
Inlet temperature: 200° C.

### Comparative Example 6

A film-forming material in the form of granules composed of gadolinium fluoride and gadolinium oxyfluoride was obtained in the same manner as in Example 7, except that, in the first step in Example 7, a 50 mass % aqueous solution of HF was added dropwise such that the molar ratio F/Gd was 1.0.

### Evaluation of Film-Forming Material

The film-forming materials obtained in Examples and Comparative Examples, and thermal-sprayed films formed from the film-forming materials were subjected to the following evaluation tests. The measured values obtained from these evaluation tests are shown in Tables 1 and 2.

### Measurement of Oxygen Content

The oxygen content of a film-forming material (mass %) was measured based on an inert gas melting-infrared absorption method (using a halogen trap).

### X-Ray Diffraction Measurement

X-ray diffraction measurement was carried out under the following condition to determine the main peak intensities (S0 to S2) of REF₃, RE-O-F, and RE₂O₃. Each of the values of X-ray diffraction peak intensity shown in Table 1 is a value of the peak intensity ratio of a crystalline phase derived from each compound relative to a main peak of the compound, expressed with the peak intensity of the main peak in a range of 2θ=20° to 60° being set to 100. The term “peak intensity ratio” as used herein means peak height ratio. However, when determining the peak intensity ratio, excluding RE₂O₃; a combination of Yb₅O₄F₇ and YbF₃; a combination of Y₁O₁F₁ and YF₃; and a combination of Gd₁O₁F₁ and GdF₃, instead of directly using the peak height of the main peak of the crystalline phase derived from each compound, the above-described peak height of the peak was used through conversion in terms of the peak height of the main peak.

The crystallite size was calculated based on X-ray diffraction measurement of the film-forming material under the following condition in accordance with JIS K 0131-1996, specifically, 12. Measurement of Crystallite Size and Inhomogeneous Strain in General Rules for X-ray Diffractometric Analysis. At this time, X-ray diffraction data obtained from the measurement performed under the following condition using CuKα rays was separated into diffraction data based on Cu-Kα rays and diffraction data based on Cu-Kα₂ rays, a diffractogram based only on Cu-Kα₁ rays was drawn to determine half width and diffraction angle. Also, as a standard substance, Si was subjected to measurement and the half width was corrected.

To be more specific, in the film-forming materials obtained in Examples 1 to 6, RE-O-F was determined to be the Y₅O₄F₇ phase. The crystallite size of YF₃ was calculated from the half width of the (020) peak, and the crystallite size of Y₅O₄F₇ was calculated from the half width of the (010 0) peak of Y₅O₄F₇ based on the Scherrer equation (D=Kλ/(β cos θ)).

In the film-forming materials obtained in Examples 7 to 10, RE-O-F was determined to be the Gd₄O₃F₆ phase. The crystallite size of each of GdF₃ and Gd₄O₃F₆ was calculated from the half width of the specific peak described above based on the Scherrer equation (D=Kλ/(β cos θ)).

In the film-forming materials obtained in Examples 11 to 13, RE-O-F was determined to be the Er₅O₄F₇ phase. The crystallite size of each of ErF₃ and Er₅O₄F₇ was calculated from the half width of the specific peak described above based on the Scherrer equation (D=Kλ/(β cos θ)).

In the film-forming materials obtained in Examples 14 to 16, RE-O-F was determined to be the Yb₅O₄F₇ phase. The crystallite size of each of YbF₃ and Yb₅O₄F₇ was calculated from the half width of the specific peak described above based on the Scherrer equation (D=Kλ/(β cos θ)).

As the value of K, 0.94 specified in JIS K 0131-1996, specifically, 12. Measurement of Crystallite Size and Inhomogeneous Strain in General Rules for X-ray Diffractometric Analysis, was used.

The crystallite size was calculated based on X-ray diffraction data obtained through measurement performed under the following condition using integrated powder X-ray diffraction software PDXL 2 Version 2.9.1.0 available from Rigaku Corporation.

For each of the film-forming materials obtained in Comparative Examples 1 to 6, the crystallite size was determined from the half width of a specific peak of a phase generated as appropriate. In the film-forming materials obtained in Comparative Examples 1 and 3 to 5, RE-O-F was determined to be the Y₅O₄F₇ phase, in the film-forming material obtained in Comparative Example 2, RE-O-F was determined to be the Y₁O₁F₁ phase, and in the film-forming material obtained in Comparative Example 6, RE-O-F was determined to be the Gd₁O₁F₁ phase.

Using the crystallite sizes obtained in the above-described manner, crystallite size ratio was determined using the following calculation formula:

$$Crystallite size ratio = crystallite size of {REF}_{3} / crystallite size of RE - O - F$$

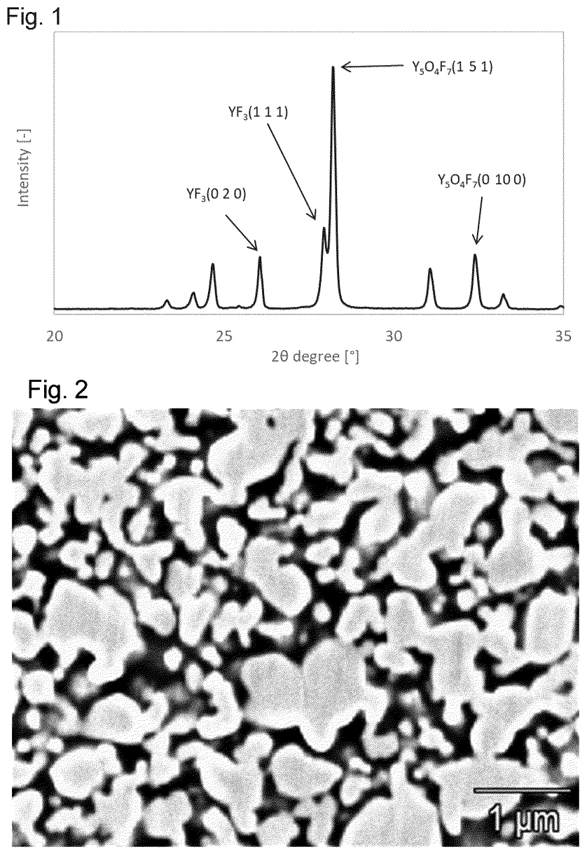

An XRD chart obtained in Example 1 is shown in FIG. 1.

### X-Ray Diffraction Measurement Condition

Apparatus: Ultima IV (available from Rigaku Corporation)
X-ray source: Cu-Kα rays
Tube voltage: 40 kV
Tube current: 40 mA
Scan speed: 2°/min
Step: 0.02°
Scanning range: 2θ=20° to 60°

### Measurement of Average Particle Size of Primary Particles

In a field of view of an SEM (with a magnification of 20,000 times) where a portion of a cross section of the granules were observed, Feret diameter was measured for each individual primary particles, and the average value of 100 primary particles with a Feret diameter corresponding to 0.1 μm or more was defined as average particle size of primary particles. The reason that the primary particles with a Feret diameter corresponding to less than 0.1 μm was excluded is to prevent the boundary between particles from being unclear and particle size measurement errors from being large. As the SEM, JSM-7900F available from JEOL Ltd. was used. The acceleration voltage was set to 4 kV.

A sample for observing a cross section of the granules was prepared in the following manner.

The granules were embedded into an epoxy resin, and then subjected to ion milling to obtain a sample with a cross section of the granules being exposed.

### Measurement of Porosity

Particle area ratio (% Area) was determined for an SEM image in the field of view of the SEM described above (with a magnification of 20,000 times and an acceleration voltage of 4 kV) using image processing software Image J by selecting options in the menu bar in the following order: Adjust→Color Threshold (Threshold Brightness 75)→Analyze Particle (particle analysis). The remaining area ratio was defined as porosity. The porosity was the average value of measured values obtained from a cross section of five granules. As the SEM image, an image of granules satisfying the above-described condition was used. An image used in the porosity measurement of the film-forming material obtained in Example 1 is shown in FIG. 2.

### Measurement of Crushing Pressure

Crushing pressure was measured in the following measurement condition using an SEM indenter.

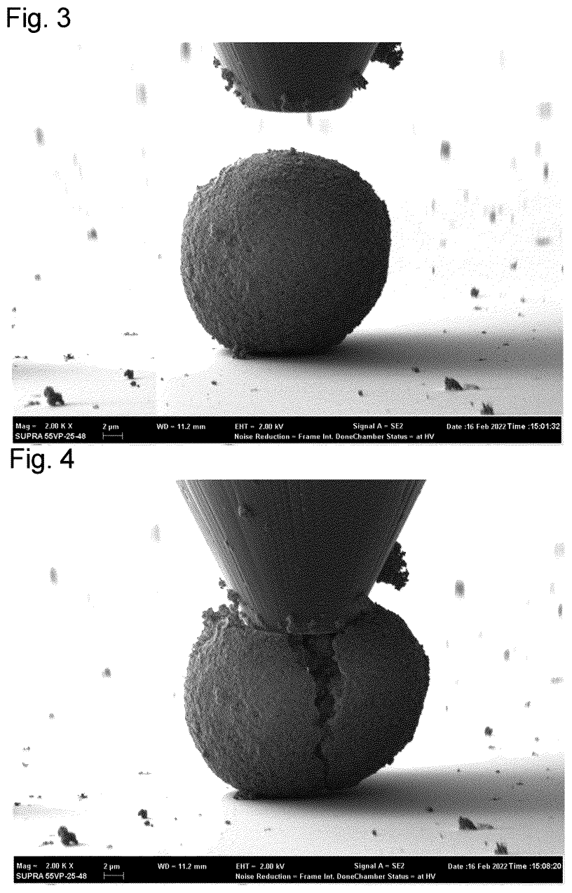

Samples subjected to the SEM indenter were each prepared by dispersing the granules on a quartz block using isopropanol (IPA) as a dispersion medium. Each sample on the quartz block prepared in the above-described manner was placed on a sample stage of an apparatus described below, and a stress-strain curve of three granules was obtained as an in-situ compression test. Then, the peak value (maximum value) of stress was read as the value of crushing stress, and divided by the area of the tip end portion of the indenter to determine crushing pressure. The average value of three granules was defined as crushing pressure. SEM images used to measure the crushing pressure of the film-forming material obtained in Example 1 are shown in FIGS. 3 and 4.

### Measurement Condition for Crushing Pressure

Apparatus: FT-NMT04 (available from Femto Tools GmbH)
Equipped SEM: SUPRA 55VP (available from Carl Zeiss, with an observation magnification of 2000 times)·
Sensor used: FT-S 20000-(registered design)-FP-10 μm
   (diamond indenter, flat punch (with an indenter tip end of φ10 μm))
Measurement mode: Compression
Indentation load: 20,000 μN at maximum
Indentation displacement: 10 μm at maximum

### Measurement of BET Specific Surface Area

BET specific surface area was determined based on a BET single-point method using Macsorb available from Mountech Co., Ltd. as a measurement apparatus. As a measurement gas, a mixed gas containing 30 volume % of nitrogen and 70 volume % of helium was used. As a calibration gas, pure nitrogen was used. A slurry subjected to BET specific surface area measurement was obtained by drying 20 g of the slurry in an environment at 120° C. for 2 hours.

### Measurement of Granule Size

Granule size was determined through measurement using Microtrac 3300 EXII available from Microtrac BEL Corporation. In the measurement, a 0.2 mass % sodium hexametaphosphate aqueous solution was used as a dispersion medium, and a sample (the granules) was added to a chamber of a sample circulator of Microtrac 3300 EXII until the apparatus determined that the concentration reached an appropriate concentration.

### Measurement of Bulk Density

Bulk density (g/cm³) was determined in accordance with JIS K 5101-12-1 using a bulk specific gravity measurement device available from Tokyo Kuramochi Scientific Instruments Co., Ltd.

TABLE 1

| | | Film-forming material | | | | | | | | |
|---|---|---|---|---|---|---|---|---|---|---|
| | | | | | XRD peak relative | | | Peak | | |
| | | Oxygen | | | intensity | | | intensity | | Crystallite |
| | | content | Composition | Composition | REF₃ | RE-O—F | RE₂O₃ | ratio | | size [nm] |
| | RE | [mass %] | of REF₃ | of RE-O—F | (S2) | (S1) | (S0) | S1/S2 | S0/S1 | S_{REF3} |
| Ex. 1 | Y | 6 | YF₃ | Y₅O₄F₇ | 33 | 100 | 0 | 3.0 | 0 | 79 |
| Ex. 2 | Y | 3 | YF₃ | Y₅O₄F₇ | 79 | 100 | 0 | 1.3 | 0 | 65 |
| Ex. 3 | Y | 1 | YF₃ | Y₅O₄F₇ | 100 | 16 | 0 | 0.16 | 0 | 80 |
| Ex. 4 | Y | 9 | YF₃ | Y₅O₄F₇ | 9 | 100 | 0 | 11 | 0 | 75 |
| Ex. 5 | Y | 3 | YF₃ | Y₅O₄F₇ | 82 | 100 | 0 | 1.2 | 0 | 76 |
| Ex. 6 | Y | 3 | YF₃ | Y₅O₄F₇ | 80 | 100 | 0 | 1.3 | 0 | 59 |
| Ex. 7 | Gd | 1 | GdF₃ | Gd₄O₃F₆ | 100 | 10 | 0 | 0.10 | 0 | 97 |
| Ex. 8 | Gd | 2 | GdF₃ | Gd₄O₃F₆ | 28 | 100 | 0 | 3.6 | 0 | 95 |
| Ex. 9 | Gd | 4 | GdF₃ | Gd₄O₃F₆ | 19 | 100 | 0 | 5.3 | 0 | 93 |
| Ex. 10 | Gd | 5 | GdF₃ | Gd₄O₃F₆ | 3 | 100 | 0 | 33 | 0 | 95 |
| Ex. 11 | Er | 1 | ErF₃ | Er₅O₄F₇ | 100 | 9 | 0 | 0.09 | 0 | 74 |
| Ex. 12 | Er | 2 | ErF₃ | Er₅O₄F₇ | 31 | 100 | 0 | 3.2 | 0 | 83 |
| Ex. 13 | Er | 4 | ErF₃ | Er₅O₄F₇ | 18 | 100 | 0 | 5.6 | 0 | 79 |
| Ex. 14 | Yb | 1 | YbF₃ | Yb₅O₄F₇ | 100 | 11 | 0 | 0.11 | 0 | 66 |
| Ex. 15 | Yb | 2 | YbF₃ | Yb₅O₄F₇ | 30 | 100 | 0 | 3.3 | 0 | 65 |
| Ex. 16 | Yb | 4 | YbF₃ | Yb₅O₄F₇ | 16 | 100 | 0 | 6.3 | 0 | 72 |
| Comp. | Y | 10 | — | Y₅O₄F₇ | 0 | 100 | 0 | — | 0 | — |
| Ex. 1 | | | | | | | | | | |
| Comp. | Y | 13 | — | Y₁O₁F₁ | 0 | 100 | 0 | — | 0 | — |
| Ex. 2 | | | | | | | | | | |
| Comp. | Y | 6 | YF₃ | Y₅O₄F₇ | 46 | 100 | 0 | 2.2 | 0 | 120 |
| Ex. 3 | | | | | | | | | | |
| Comp. | Y | 7 | YF₃ | Y₅O₄F₇ | 28 | 100 | 0 | 3.6 | 0 | 102 |
| Ex. 4 | | | | | | | | | | |
| Comp. | Y | 3 | YF₃ | Y₅O₄F₇ | 81 | 100 | 0 | 1.2 | 0 | 60 |
| Ex. 5 | | | | | | | | | | |
| Comp. | Gd | 8 | — | Gd₁O₁F₁ | 0 | 100 | 0 | — | 0 | — |
| Ex. 6 | | | | | | | | | | |

| | Film-forming material | | | | | | | |
|---|---|---|---|---|---|---|---|---|
| | | | Average | | | | | |
| | | | particle | | | | BET | |
| | | | size of | | | | specific | |
| | Crystallite | Crystallite | primary | | Crushing | Granule | surface | Bulk |
| | size [nm] | size ratio | particles | Porosity | pressure | size | area | density |
| | S_{RE-O—F} | (S_{REF3}/S_{RE-O—F}) | [μm] | [%] | [kPa] | [μm] | [m²/g] | [g/com³] |
| Ex. 1 | 61 | 1.30 | 0.5 | 24 | 85 | 30 | 4 | 1.4 |
| Ex. 2 | 53 | 1.23 | 0.4 | 31 | 112 | 31 | 4 | 1.3 |
| Ex. 3 | 66 | 1.21 | 0.5 | 30 | 92 | 32 | 2 | 1.4 |
| Ex. 4 | 58 | 1.29 | 0.5 | 28 | 83 | 30 | 3 | 1.4 |
| Ex. 5 | 63 | 1.21 | 0.5 | 22 | 43 | 45 | 2 | 1.4 |
| Ex. 6 | 48 | 1.23 | 0.2 | 32 | 59 | 16 | 6 | 1.3 |
| Ex. 7 | 96 | 1.01 | 0.4 | 25 | 117 | 29 | 2 | 2.0 |
| Ex. 8 | 88 | 1.08 | 0.4 | 21 | 80 | 29 | 2 | 2.2 |
| Ex. 9 | 89 | 1.04 | 0.5 | 24 | 70 | 30 | 2 | 2.1 |
| Ex. 10 | 86 | 1.10 | 0.4 | 18 | 76 | 30 | 3 | 2.3 |
| Ex. 11 | 65 | 1.14 | 0.4 | 27 | 103 | 26 | 2 | 2.2 |
| Ex. 12 | 68 | 1.22 | 0.4 | 17 | 93 | 29 | 2 | 2.1 |
| Ex. 13 | 67 | 1.18 | 0.6 | 20 | 39 | 28 | 2 | 2.2 |
| Ex. 14 | 56 | 1.18 | 0.6 | 26 | 57 | 31 | 1 | 2.3 |
| Ex. 15 | 57 | 1.14 | 0.5 | 26 | 101 | 29 | 2 | 2.2 |
| Ex. 16 | 62 | 1.16 | 0.4 | 23 | 104 | 30 | 2 | 2.4 |
| Comp. | 59 | — | 0.7 | 29 | 28 | 44 | 2 | 1.3 |
| Ex. 1 | | | | | | | | |
| Comp. | 66 | — | 0.6 | 25 | 25 | 43 | 2 | 1.2 |
| Ex. 2 | | | | | | | | |
| Comp. | 82 | 1.46 | 1.1 | 36 | 23 | 48 | 1 | 1.3 |
| Ex. 3 | | | | | | | | |
| Comp. | 73 | 1.40 | 1.2 | 38 | 229 | 27 | 1 | 1.6 |
| Ex. 4 | | | | | | | | |
| Comp. | 95 | 0.63 | 0.8 | 42 | 5 | 37 | 1 | 1.3 |
| Ex. 5 | | | | | | | | |
| Comp. | 104 | — | 0.7 | 33 | 32 | 29 | 2 | 1.9 |
| Ex. 6 | | | | | | | | |

As shown in Table 1, in all of the film-forming materials obtained in Examples, the rare earth fluoride (REF₃) and the rare earth oxyfluoride (RE-O-F) were observed in the X-ray diffraction measurement, and the crystallite size ratio S_{REF3}/S_{RE-O-F} was 0.90 or more and 1.35 or less. On the other hand, in the film-forming materials obtained in Comparative Examples 1, 2, and 6, the rare earth fluoride (REF₃) was not observed, and in the film-forming materials obtained in Comparative Examples 3 to 5, the crystallite size ratio S_{REF3}/S_{RE-O-F} was outside the range of 0.90 or more and 1.35 or less.

### Production of Thermal-Sprayed Film

A thermal-sprayed film was formed in the following manner using each of the film-forming materials obtained in Examples and Comparative Examples.

As a substrate, an aluminum alloy plate was used. Plasma thermal spraying was performed on the surface of the substrate. As an apparatus for supplying the film-forming material, TWIN-SYSTEM 10-V available from Plasma Technik AG was used. As a plasma thermal spraying apparatus, F4 available from Sulzer Metco Japan, Ltd. was used.

Plasma thermal spraying was performed under the following condition until a film with a thickness of 150 μm was obtained.
Stirring speed: 50%
Carrier gas flow rate: 2.5 L/min
Supply scale: 10%
Plasma gas: Ar/H₂
Output: 35 KW
Apparatus-to-substrate distance: 150 mm.

### Analysis of Film Composition

The films of Examples and Comparative Examples obtained in the above-described manner were subjected to XRD measurement performed in the same manner as that performed for the film-forming materials to determine main peak intensity ratio.

### Measurement of Film Surface Roughness

Surface roughness was measured for each thermal-sprayed film formed on a 20 mm square aluminum alloy plate based on the above-described method.

Using a stylus-type surface roughness measurement device (JIS B0651: 2001), arithmetic average roughness (Ra) and maximum height roughness (Rz) (JIS B 0601:2001) were determined. As the stylus-type surface roughness measurement device, SJ-210 available from Mitutoyo Corporation was used. The measurement condition was as follows.
Evaluation length: 5 mm
Measurement speed: 100 μm/s.

The average value of measured values obtained at three points was determined.

### Film Porosity

In each thermal-sprayed film formed on a 20 mm square (with a thickness of 5 mm) aluminum alloy plate based on the above-described method, an area of 20 mm×5 mm was mirror polished and observed using an SEM (with a magnification of 1,000 times and an acceleration voltage of 10 kV). A cross section of the coating film observed in the field of view of the SEM was subjected to image processing performed in the same manner as that performed when measuring the porosity described above to calculate the porosity of the film.

### Measurement of Etching Rate

In each thermal-sprayed film formed on a 20 mm square (with a thickness of 5 mm) aluminum alloy plate based on the above-described method, a piece of kapton tape was attached to one half of the coating film, the coating film was placed in a chamber of an etching apparatus (RIE-10NR available from Samco, Inc.), with the coating film facing upward, and plasma etching was performed. The plasma etching was performed under the following condition.

The etching rate was determined by measuring, based on the above-described surface roughness measurement, a difference between a plasma-exposed surface and a non-exposed surface from which the tape had been removed after plasma irradiation. For each coating film, measurement was performed at three points, and the average value of measured values obtained at the three points was determined.

### Plasma Etching Condition

Atmosphere gas: CF₄/O₂/Ar=40/20/40 (cc/min)·
High-frequency power: RF 300 W
Pressure: 5 Pa
Etching time: 5 hours

TABLE 2

| | | | | Thermal-sprayed film | | | | | | | | |
|---|---|---|---|---|---|---|---|---|---|---|---|---|
| | | | | XRD peak relative intensity | | | | | | | | |
| | | | | REF₃ | | | XRD peak | | Surface | | | |
| | | | | (including a | | | intensity | | roughness | | | Etching |
| | | Composition | Composition | heterophase) | RE-O—F | RE₂O₃ | ratio | | [μm] | | Porosity | rate |
| | RE | of REF₃ | of RE-O—F | S2′ | S1′ | S0′ | S1′/S2′ | S0′/S1′ | Ra | Rz | [%] | [nm/min] |
| Ex. 1 | Y | YF₃ | Y₅O₄F₇ | 10 | 100 | 0 | 10 | 0 | 4.7 | 28 | 2 | 4.8 |
| Ex. 2 | Y | YF₃ | Y₅O₄F₇ | 28 | 100 | 0 | 3.6 | 0 | 4.7 | 27 | 0 | 4.4 |
| Ex. 3 | Y | YF₃ | Y₅O₄F₇ | 100 | 80 | 0 | 0.8 | 0 | 5.4 | 31 | 4 | 4.9 |
| Ex. 4 | Y | YF₃ | Y₅O₄F₇ | 0 | 100 | 1 | — | 0.01 | 5.1 | 27 | 5 | 4.9 |
| Ex. 5 | Y | YF₃ | Y₅O₄F₇ | 36 | 100 | 0 | 2.8 | 0 | 6.1 | 35 | 0 | 4.2 |
| Ex. 6 | Y | YF₃ | Y₅O₄F₇ | 13 | 100 | 0 | 7.7 | 0 | 3.4 | 20 | 3 | 4.8 |
| Ex. 7 | Gd | GdF₃ | Gd₄O₃F₆ | 100 | 6 | 0 | 0.06 | 0 | 3.4 | 21 | 1 | 3.9 |
| Ex. 8 | Gd | GdF₃ | Gd₄O₃F₆ | 36 | 100 | 0 | 2.8 | 0 | 3.7 | 22 | 0 | 3.9 |
| Ex. 9 | Gd | GdF₃ | Gd₄O₃F₆ | 5 | 100 | 0 | 20 | 0 | 3.8 | 22 | 2 | 3.7 |
| Ex. 10 | Gd | GdF₃ | Gd₄O₃F₆ | 0 | 100 | 0 | — | 0 | 4.0 | 24 | 4 | 4.2 |
| Ex. 11 | Er | ErF₃ | Er₅O₄F₇ | 100 | 7 | 0 | 0.07 | 0 | 3.0 | 18 | 0 | 4.4 |
| Ex. 12 | Er | ErF₃ | Er₅O₄F₇ | 40 | 100 | 0 | 2.5 | 0 | 3.3 | 20 | 0 | 3.8 |
| Ex. 13 | Er | ErF₃ | Er₅O₄F₇ | 8 | 100 | 0 | 13 | 0 | 3.5 | 23 | 3 | 4.1 |
| Ex. 14 | Yb | YbF₃ | Yb₅O₄F₇ | 100 | 10 | 0 | 0.1 | 0 | 3.4 | 20 | 1 | 4.5 |
| Ex. 15 | Yb | YbF₃ | Yb₅O₄F₇ | 36 | 100 | 0 | 2.8 | 0 | 3.5 | 21 | 0 | 4.1 |
| Ex. 16 | Yb | YbF₃ | Yb₅O₄F₇ | 0 | 100 | 0 | — | 0 | 3.9 | 23 | 2 | 4.0 |
| Comp. | Y | — | Y₅O₄F₇ | 0 | 100 | 20 | — | 0.2 | 6.5 | 37 | 18 | 6.0 |
| Ex. 1 | | | | | | | | | | | | |
| Comp. | Y | — | Y₁O₁F₁ | 0 | 100 | 54 | — | 0.54 | 6.8 | 39 | 24 | 7.8 |
| Ex. 2 | | | | | | | | | | | | |
| Comp. | Y | YF₃ | Y₅O₄F₇ | 12 | 100 | 3 | 8.3 | 0.03 | 5.3 | 49 | 8 | 5.4 |
| Ex. 3 | | | | | | | | | | | | |
| Comp. | Y | YF₃ | Y₅O₄F₇ | 5 | 100 | 4 | 20 | 0.04 | 3.6 | 24 | 9 | 5.7 |
| Ex. 4 | | | | | | | | | | | | |
| Comp. | Y | YF₃ | Y₅O₄F₇ | 11 | 100 | 0 | 9.1 | 0 | 8.2 | 75 | 15 | 6.0 |
| Ex. 5 | | | | | | | | | | | | |
| Comp. | Gd | — | Gd₁O₁F₁ | 0 | 100 | 11 | — | 0.11 | 4.2 | 25 | 20 | 6.4 |
| Ex. 6 | | | | | | | | | | | | |

The expression “including a heterophase” means that a modified product generated through thermal spraying is present in REF₃.

In Table 2, the thermal-sprayed films of Examples generally have a smaller surface roughness than thermal-sprayed films of Comparative Examples. Also, the thermal-sprayed films of Examples have a smaller porosity that that of the thermal-sprayed films of Comparative Examples, and the etching rate is lower. Accordingly, it can be seen that the films formed from the film-forming materials obtained in Examples are denser and have more excellent corrosion resistance to plasma etching as compared with the films obtained in Comparative Examples.

### INDUSTRIAL APPLICABILITY

According to the present invention, it is possible to provide a film-forming material, with which it is possible to produce a coating film that is dense and has excellent corrosion resistance to plasma etching.

1. A film-forming material in which a rare earth fluoride (REF₃) and a rare earth oxyfluoride (RE-O-F) are observed in X-ray diffraction measurement,
wherein S_{REF3}/S_{RE-O-F} that is a ratio of a crystallite size (S_{REF3}) of REF₃ relative to a crystallite size (S_{RE-O-F}) of RE-O-F is 0.90 or more and 1.35 or less.

2. The film-forming material according to claim 1,
wherein the crystallite size of each of REF₃ and RE-O-F is 40 nm or more and 100 nm or less.

3. The film-forming material according to claim 1,
wherein primary particles observed using a scanning electron microscope (SEM) have an average particle size of 0.1 μm or more and 1.0 μm or less.

4. The film-forming material according to claim 1,
wherein the film-forming material is in a form of granules.

5. The film-forming material according to claim 4,
wherein a porosity in an internal cross section of the granules observed using an SEM is 10% or more and 35% or less.

6. The film-forming material according to claim 4,
wherein the film-forming material in the form of granules has a crushing pressure measured using an SEM indenter of 25 kPa or more and 130 kPa or less.

7. The film-forming material according to claim 4,
wherein the film-forming material in the form of granules has an average granule particle size of 10 μm or more and 60 μm or less.

8. The film-forming material according to claim 1,
wherein granules have a bulk density of 1.3 g/cm³ or more.

9. The film-forming material according to claim 1,
wherein the film-forming material has an oxygen content of 1 mass % or more and 9 mass % or less.

10. The film-forming material according to claim 1,
wherein the rare earth element (RE) is at least one selected from yttrium (Y), gadolinium (Gd), erbium (Er), and ytterbium (Yb).

11. A method for producing a coating film comprising:
forming the film-forming material according to claim 1 into the coating film based on a thermal spray method or a PVD method.
